(19) United States
(12) Patent Application Publication
(10) Pub. No.: US 2007/0037326 A1
(43) Pub. Date: Feb. 15, 2007

(54) Shallow source/drain regions for CMOS transistors

(75) Inventors: Chien-Hao Chen, Chuangwei Township (TW); Chun-Feng Nieh, Baoshan Township (TW); Tze-Liang Lee, Hsinchu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/200,374

(22) Filed: Aug. 9, 2005

(51) Int. Cl. H01L 21/84

(52) U.S. Cl. 438/151; 257/E21.415

(57) ABSTRACT

A transistor having shallow, high-dopant concentration source/drain regions is provided. A gate electrode is formed on a substrate, and the source/drain regions of the substrate are transformed into an amorphous state by, for example, implanting Si, Ge, Xe, In, Ar, Kr, Rn, a combination thereof, or the like ions. A co-implantation process is performed to implant ions of C, N, F, a combination thereof, or the like in the source/drain regions. Thereafter, one or more implants may be performed to form the LDD and source/drain regions and the substrate is recrystallized. The amorphous regions and the co-implantation regions effectively confine or reduce the diffusion of the ions used to form the LDD and source/drain regions.

### TECHNICAL FIELD

The present invention relates generally to semiconductor devices, and more particularly, to source/drain regions for complementary metal oxide-semiconductor transistors.

### BACKGROUND

Complementary metal-oxide-semiconductor (CMOS) technology is the dominant semiconductor technology used for the manufacture of ultra-large scale integrated (ULSI) circuits today. Size reduction of the semiconductor structures has provided significant improvement in the speed, performance, circuit density, and cost per unit function of semiconductor chips over the past few decades. Significant challenges, however, are faced as the sizes of CMOS devices continue to decrease.

For example, as the length of the gate electrode of a CMOS transistor is reduced, particularly with gate lengths of less than about 30 nm, the source and drain regions increasingly interact with the channel and gain influence on the channel potential and the gate dielectric. Consequently, a transistor with a short gate length suffers from problems related to the inability of the gate electrode to substantially control the on and off states of the channel. Phenomena such as reduced gate control associated with transistors with short channel lengths are termed short-channel effects.

To reduce the short-channel effects, it is desirable to fabricate CMOS devices with shallower lightly-doped drains (LDD) and/or source/drain junctions. This is particularly true with PMOS devices, which have the LDD and source/drain regions that are typically formed of a P-type dopant, such as boron or BF₂. It has been found that these P-type dopants may exhibit high diffusability away from the originally implanted region after subsequent spacer and anneal steps. This high diffusability causes the LDD and source/drain regions to expand vertically and horizontally, thereby causing undesirable short-channel effects as discussed above.

One attempt to limit the diffusability involves scaling the source/drain regions accordingly as the size decreases. Scaling source/drain regions, however, tends to increase the resistance of the source/drain and deteriorates the polysilicon gate depletion. As a result, scaling the source/drain junctions may degrade the drive currents of the PMOS devices.

Accordingly, there is a need for a source/drain region that reduces or eliminates the short-channel effects while maintaining an acceptable source/drain resistance and drive current levels as the sizes of CMOS devices are reduced.

### SUMMARY OF THE INVENTION

These and other problems are generally reduced, solved or circumvented, and technical advantages are generally achieved, by embodiments of the present invention, which provides an amorphization process and a co-implant process in fabricating source/drain regions of a semiconductor device.

In an embodiment of the present invention, a transistor having shallow source/drain regions is provided. The transistor may be fabricated by forming a gate electrode over a substrate. The source/drain regions of the substrate are transformed into an amorphous state, and a co-implant process is performed to implant C, N, F, a combination thereof, or the like ions into the source/drain regions. Thereafter, the source/drain regions of the transistor may be doped with a conductive-type ion, such as B, BF₂, or the like. The amorphous regions of the source/drain regions are re-crystallized and the source/drain regions may be activated by, for example, performing an anneal.

In an embodiment, the source/drain regions of the substrate are transformed into an amorphous state by performing implanting, for example, Si, Ge, Xe, In, Ar, Kr, Rn, a combination thereof, or the like ions.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-6 are cross-sectional views of a wafer after various process steps are performed in accordance with one embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

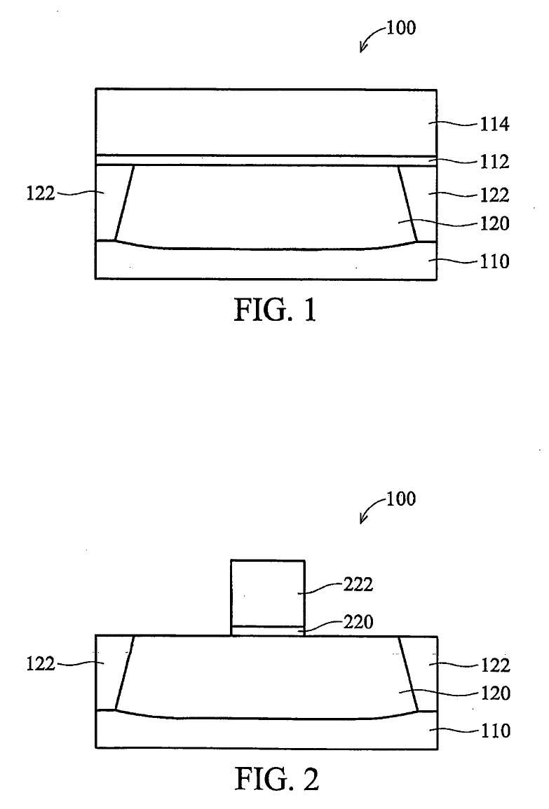

FIGS. 1-6 illustrate an embodiment for fabricating a PMOS transistor using an amorphization process and a co-implant process in accordance with an embodiment of the present invention. The amorphization and co-implant processes have been found to limit the lateral/vertical diffusion of the source/drain implants. As a result, higher dopant concentrations may be used to form shallower source/drain regions while reducing or eliminating the short-channel effects. It should be noted, however, that embodiments of the present invention are described in the context of fabricating PMOS transistors that implant B or BF₂ ions in the source/drain regions for illustrative purposes only and that embodiments of the present invention may be used to fabricate NMOS transistors, PMOS transistors using dopants other than B or BF₂, or other types of devices, such as capacitors, resistors, or the like.

Furthermore, embodiments of the present invention may be used in a variety of circuits. For example, embodiments of the present invention may be useful in I/O devices, core devices, memory circuits, system-on-chip (SoC) devices, other integrated circuits, and the like. Embodiments of the present invention may be particularly useful in sub-65 nm designs where short-channel effects may be more troublesome.

Referring first to FIG. 1, a wafer 100 is shown comprising a substrate 110 having a dielectric layer 112 and a conductive layer 114 formed thereon in accordance with an embodiment of the present invention. In an embodiment, the substrate 110 comprises a P-type bulk silicon substrate having an N-well 120 in which PMOS devices may be formed. Other materials, such as germanium, silicon-germanium alloy, or the like, could alternatively be used for the substrate 110. The substrate 110 may also be an active layer of a semiconductor-on-insulator (SOI) substrate or a multi-layered structure such as a silicon-germanium layer formed on a bulk silicon layer. The N-well 120 may be formed by implantation with, for example, phosphorous ions at a dose of about 1e12 to about 1e14 atoms/cm² and at an energy of about 10 to about 200 KeV. Other N-type dopants, such as nitrogen, arsenic, antimony, or the like, may also be used.

Shallow-trench isolations (STIs) 122, or some other isolation structures such as field oxide regions, may be formed in the substrate 110 to isolate active areas on the substrate. The STIs 122 may be formed by etching trenches in the substrate and filling the trenches with a dielectric material, such as silicon dioxide, a high-density plasma (HDP) oxide, or the like, as known in the art.

The dielectric layer 112 comprises a dielectric material, such as silicon dioxide, silicon oxynitride, silicon nitride, a nitrogen-containing oxide, a high-K metal oxide, a combination thereof, or the like. A silicon dioxide dielectric layer may be formed, for example, by an oxidation process, such as wet or dry thermal oxidation. In the preferred embodiment, the dielectric layer 112 is about 5 Å to about 100Å in thickness.

The conductive layer 114 comprises a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped polysilicon, other conductive materials, or a combination thereof. In an embodiment, the polysilicon layer is formed by low-pressure chemical vapor deposition (LPCVD) to a thickness in the range of about 200 Å to about 2000 Å, but more preferably about 1000 Å.

FIG. 2 illustrates the wafer 100 of FIG. 1 after the dielectric layer 112 and the conductive layer 114 of FIG. 1 have been patterned to form a gate dielectric 220 and gate electrode 222, respectively, in accordance with an embodiment of the present invention. The gate dielectric 220 and the gate electrode 222 may be patterned by photolithography techniques as are known in the art. Generally, photolithography involves depositing a photoresist material (not shown), which is then masked, exposed, and developed. After the photoresist material is patterned, an anisotropic etching process may be performed to remove unwanted portions of the photoresist material. Thereafter, an etching process may be performed to remove unwanted portions of the dielectric layer 112 (FIG. 1) and the conductive layer 114 (FIG. 1) to form the gate dielectric 220 and the gate electrode 222, respectively, as illustrated in FIG. 2. Remaining portions of the photoresist material may be removed after forming the gate dielectric 220 and gate electrode 222.

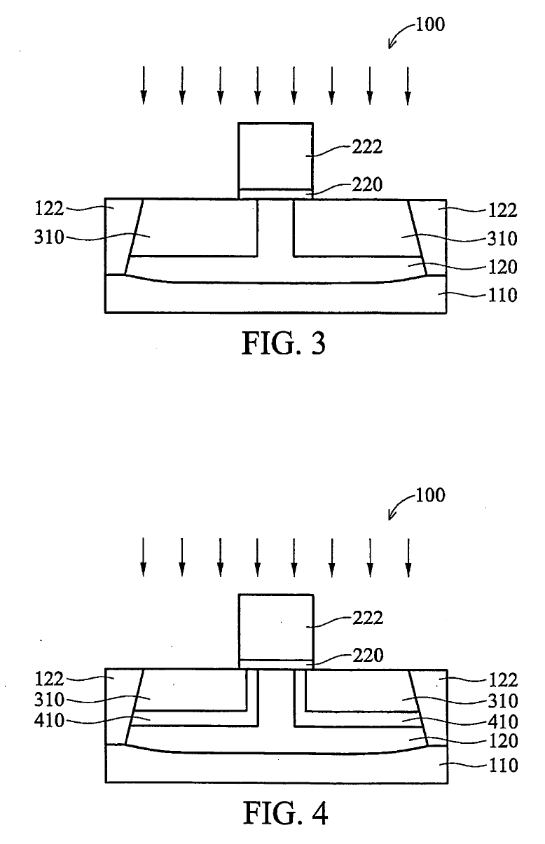

FIG. 3 illustrates the wafer 100 of FIG. 2 after an amorphization region 310 has been formed in accordance with an embodiment of the present invention. The amorphization region 310 represents an area in which the crystalline structure of the substrate 110 has been transformed into an amorphous state. The amorphization region 310 may be formed by an implantation process using Ge, Si, or inert gas (such as Ne, Ar, Kr, Xe, Rn, or the like) ions at a dose of about 1e14 to about 1e16 atoms/cm². Preferably the energy level is selected such that the depth of the amorphization region 310 is deeper than the subsequently formed LDD regions as implanted. In an embodiment, the amorphization region 310 is performed by implantation at an energy of about 5 to about 50 KeV to form an amorphization region 310 having a depth of about 100 Å to about 500 Å.

During the amorphization process, the gate electrode 222 may be partially transformed to the amorphous state, but may be re-crystallized when the amorphization region 310 is re-crystallized in subsequent steps. Nevertheless, a mask may be used to protect the gate electrode 222 and prevent the gate electrode 222 from being transformed to an amorphous state. The mask may be, for example, a photoresist mask and/or a hard mask, such as the mask used to pattern the gate electrode 222 and gate dielectric 220.

FIG. 4 illustrates the wafer 100 of FIG. 3 after a co-implantation region 410 has been formed in accordance with an embodiment of the present invention. The co-implantation region 410 may be formed by implanting carbon, fluorine, and/or nitrogen ions at a dose of about 0.1 to about 1.0 times the dosage to be used to form the LDD and/or source/drain regions in subsequent processing steps and at an energy of about 1 to about 10 KeV. Preferably, the co-implantation region 410 has a depth approximately equivalent to the depth of the amorphization region 310, or greater, and preferably, has a depth greater than the subsequently formed LDD and source/drain regions as implanted.

The co-implantation region 410 reduces the transient diffusion of the dopants (e.g., B, BF₂, or the like) used to form the LDD and source/drain regions in subsequent processing steps. By reducing the transient diffusion, shallower source/drain regions may be formed while reducing or limiting the short-channel effects and maintaining higher drive currents.

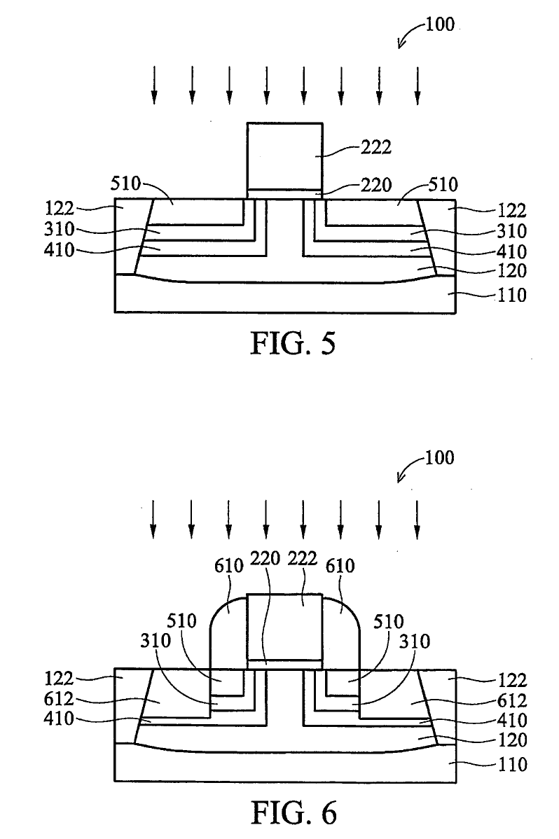

FIG. 5 illustrates the wafer 100 of FIG. 4 after first implant regions 510 have been formed in accordance with an embodiment of the present invention. The first implant regions 510 form lightly-doped drain (LDD) regions for the PMOS transistor. The first implant regions 510 may be doped with, for example, a P-type dopant, such as boron or BF₂ ions at a dose of about 1E15 to about 1E17 atoms/cm² and at an energy of about 0.1 to about 10 KeV. Alternatively, the first implant regions 510 may be doped with other P-type dopants such as aluminum, gallium, indium, or the like.

One of ordinary skill in the art will appreciate, because the amorphization regions 310 and co-implantation regions 410 reduce the lateral diffusion of the LDD region, higher doses may be used to form the LDD regions. The use of higher dose LDD regions may reduce the junction resistance and increase drive currents.

FIG. 6 illustrates the wafer 100 of FIG. 5 after first implant spacers 610 have been formed and second implant regions 612 have been formed in accordance with an embodiment of the present invention. The first implant spacers 610, which form implant masks for a second ion implant in the source/drain regions, preferably comprise a nitrogen-containing layer, such as silicon nitride (Si₃N₄), silicon oxynitride SiOₓN_{y}, silicon oxime SiOₓN_{y}:H_{z}, a combination thereof, or the like. In a preferred embodiment, the first implant spacers 610 are formed from a layer comprising Si₃N₄ that has been formed using chemical vapor deposition (CVD) techniques using silane and ammonia (NH₃) as precursor gases. Other materials and processes, however, may be used.

The first implant spacers 610 may be patterned by performing an isotropic or anisotropic etch process, such as an isotropic etch process using a solution of phosphoric acid (H₃PO₄). Because the thickness of the layer of Si₃N₄ (or other material) is greater in the regions adjacent the gate electrode 222, the isotropic etch removes the Si₃N₄ material except for that material adjacent the gate electrode 222, thereby forming the first implant spacers 610 as illustrated in FIG. 6.

It should be noted that other types of spacers, doping profiles, and implant masks may be used. For example, multiple spacers, disposable spacers, offset spacers, liners, and the like may be used. Accordingly, embodiments of the present invention may utilize different doping profiles.

The second implant regions 612 may be formed by implanting a P-type dopant, such as boron or BF₂ ions at a dose of greater than about 1E15 to about 1E17 atoms/cm² and at an energy of about 1 to about 50 KeV. Alternatively, the second implant regions 612 may be doped with other P-type dopants such as aluminum, gallium, indium, or the like. It should be noted that the second implant regions 612 may extend through the amorphization region 310.

Thereafter, the amorphization region 310 is re-crystallized. In an embodiment, the amorphization region 310 is re-crystallized by performing an anneal, such as an RTA, wherein the crystallized silicon (e.g., the silicon beneath the gate dielectric 220 and the amorphization region 310) act as a seed layer. It should be noted that subsequent anneals performed during standard processing steps to complete fabrication of the semiconductor device may be used to re-crystallize the amorphization region 310. In another embodiment, a separate anneal may be performed to re-crystallize the amorphization region 310. The gate electrode 222 may also be re-crystallized during this process.

Standard processing techniques may be used to complete fabrication of the semiconductor device. For example, the source/drain regions and the gate electrode may be silicided, inter-layer dielectrics may be formed, contacts and vias may be formed, metal lines may be fabricated, and the like.

As one of ordinary skill in the art will appreciate, embodiments of the present invention provide several advantages. For example, due to the amorphization and co-implant procedures discussed above, the diffusion (lateral and vertical) of the dopants may be prevented and/or reduced. In this manner, the first implant regions 510 and the second implant regions 612 may be shallower and contain a higher concentration of dopants than previously available in the prior art. The shallower first implant regions 510 and second implant regions 612 reduce or eliminate the short-channel effects and gate poly-depletion issues while maintaining a high drive current.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a semiconductor device, the method comprising:
providing a substrate;
forming a gate electrode over the substrate;
forming amorphization regions in the substrate on opposing sides of the gate electrode;
forming co-implantation regions of a first ion type in the substrate on opposing sides of the gate electrode, the co-implantation region having a depth approximately the same as or greater than the amorphization region and overlapping the amorphization region;
forming a first implant region of a second ion type in each of the co-implantation regions;
forming one or more spacers adjacent the gate electrode;
forming one or more second implant regions of the second ion type in each of the co-implantation regions; and
at least partially re-crystallizing the amorphization regions after forming one or more second implant regions.

2. The method of claim 1, wherein the forming a first implant region and the forming one or more second implant regions includes implanting ions at a dose of about 1E15 to about 1E17 atoms/cm².

3. The method of claim 1, wherein the second ion type is B, BF₂, or a combination thereof.

4. The method of claim 1, wherein the forming the amorphization regions is performed at least in part by an implantation procedure.

5. The method of claim 1, wherein the forming the amorphization regions is performed by implanting ions of Ge, Xe, Si, In, Ar, Kr, Rn, or a combination thereof.

6. The method of claim 1, wherein the forming co-implantation regions is performed by implanting at a dose of about 0.1 to about 10.0 times a dose used in the forming a first implant region.

7. The method of claim 1, wherein the first ion type is carbon, nitrogen, fluorine, or a combination thereof.

8. A method of forming a semiconductor device, the method comprising:
providing a substrate;
forming a gate electrode over the substrate;
forming amorphization regions in the substrate on opposing sides of the gate electrode;
forming co-implantation regions in the substrate on opposing sides of the gate electrode, the co-implantation region having a depth approximately the same as or greater than the amorphization region and overlapping the amorphization region;
forming LDD regions on opposing sides of the gate electrode, the LDD regions being contained within the co-implantation regions;
forming spacers adjacent the gate electrode;
forming deep source/drain regions in the substrate on opposing sides of the gate electrode in the co-implantation regions; and
at least partially re-crystallizing the amorphization regions after the forming deep source/drain regions.

9. The method of claim 8, wherein the forming an LDD and the forming deep source/drain regions includes implanting ions at a dose of about 1E15 to about 1E17 atoms/cm².

10. The method of claim 8, wherein the forming the LDD regions and the forming the deep source/drain regions include implanting ions of B, BF₂, or a combination thereof.

11. The method of claim 8, wherein the forming the amorphization regions is performed at least in part by an implantation procedure.

12. The method of claim 8, wherein the forming the amorphization regions includes implanting ions of Ge, Xe, Si, In, Ar, Kr, Rn, or a combination thereof.

13. The method of claim 8, wherein the forming the co-implantation regions includes implanting ions of carbon, nitrogen, fluorine, or a combination thereof.

14. The method of claim 13, wherein the ions of carbon, nitrogen, fluorine, or a combination are implanted at a dose of about 0.1 to about 10.0 times a dose used in the forming the LDD regions.

15. A method of forming a semiconductor device, the method comprising:
providing a substrate;
forming a gate electrode over the substrate;
amorphizing a first portion of the substrate on opposing sides of the gate electrode;
implanting a first ion type into a second portion of the substrate on opposing sides of the gate electrode, the first portion and the second portion overlapping;
implanting a second ion type to form one or more implant regions in each of the second portions; and
at least partially re-crystallizing the first portion after forming the one or more implant regions.

16. The method of claim 15, wherein the implanting a second ion type includes implanting ions at a dose of about 1E15 to about 1E17 atoms/cm².

17. The method of claim 15, wherein the second ion type is B, BF₂, or a combination thereof.

18. The method of claim 15, wherein the amorphizing is performed by implanting ions of Ge, Xe, Si, In, Ar, Kr, Rn, or a combination thereof.

19. The method of claim 15, wherein the implanting of the first ion type is performed with a dose of about 0.1 to about 10.0 times a dose used in the implanting the second ion type.

20. The method of claim 15, wherein the first ion type is carbon, nitrogen, fluorine, or a combination thereof.
